(19) United States
(12) Patent Application Publication
(10) Pub. No.: US 2026/0314003 A1
(43) Pub. Date: Oct. 8, 2026

(54) STRUCTURE INCLUDING AN INTERFACIAL LAYER AND METHOD OF FORMING SAME

(71) Applicant: ASM IP Holding B.V., Almere (NL)

(72) Inventors: Angada Sachid, Scottsdale, AZ (US); Fu Tang, Gilbert, AZ (US); Andrea Illiberi, Gilbert, AZ (US); Vivek Koladi Mootheri, Leuven (BE); Michael Eugene Givens, Scottsdale, AZ (US); Mihaela Balseanu, Scottsdale, AZ (US); Eric James Shero, Phoenix, AZ (US)

(21) Appl. No.: 19/632,636

(22) Filed: Mar. 30, 2026

Related U.S. Application Data
(60) Provisional application No. 63/782,139, filed on Apr. 2, 2025.

(51) Int. Cl. H10D 64/01; H10D 64/66

(52) U.S. Cl. CPC H10D 64/0132; H10D 64/01338; H10D 64/01342; H10D 64/01346; H10D 64/668

(57) ABSTRACT

Methods for forming a structure including an interfacial layer are disclosed. An exemplary method includes providing a substrate in a reaction chamber, forming an interfacial layer, and forming a high-k dielectric layer. The interfacial layer may be a bilayer of a first interfacial sub-layer comprising silicon oxide and a second interfacial sub-layer comprising a metal silicate, or a silicon oxide doped with a metal.

### CROSS-REFERENCE TO RELATED APPLICATIONS

This application is a nonprovisional of, and claim priority to and the benefit of, U.S. Provisional Patent Application No. 63/782,139, filed Apr. 2, 2025 and entitled “STRUCTURE INCLUDING AN INTERFACIAL LAYER AND METHOD OF FORMING SAME,” which is hereby incorporated by reference herein.

### FIELD

The disclosure generally relates to methods of and apparatuses for forming structures, such as structures suitable for use in forming electronic devices. More particularly, examples of the disclosure relate to methods for forming a structure comprising an interfacial layer and to structures formed using such methods.

### BACKGROUND

The scaling of semiconductor devices has led to significant improvements in speed and density of integrated circuits. The scaling of semiconductor devices, however, has presented challenges. For example, in the formation of field effect transistors and similar devices, scaling down of such devices has been problematic in some cases. Field effect transistors and similar devices typically include a gate stack. A typical gate stack includes an interfacial layer. Scaling down interfacial layers within such structures that maintain relatively high dielectric constants (high-k materials), while achieving relatively low equivalent oxide thickness (EOT) or capacitance equivalence thickness (CET) has been particularly challenging. Using current methods, an interfacial layer may contribute more than 70% of the EOT of a gate stack. Thus, there exists a desire for improved interfacial layers and improved methods for forming interfacial layers within gate stacks that lower EOT or CET while maintaining desirable properties, such as a high band gap and good interfacial properties.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Various examples described herein relate to methods for forming a structure, such as a gate stack, and more specifically a (e.g., gate stack) structure that includes an interfacial layer. As set forth below, methods described herein may be used in the fabrication of electronic devices, such as semiconductor devices.

According to one or more embodiments, a method of forming a structure is provided. An exemplary method includes providing a substrate in a reaction chamber, forming at least a portion of an interfacial layer, forming a high-k dielectric layer on the interfacial layer, and optionally forming one or more additional layers on the high-k dielectric. In some embodiments, the one or more additional layers can include one or more conductive layers to complete a gate stack.

In some embodiments, forming at least a portion of the interfacial layer includes providing a first interfacial sub-layer comprising silicon oxide on a surface of the substrate and forming a second interfacial sub-layer comprising a metal silicate on the first interfacial sub-layer. Alternatively, forming the interfacial layer includes forming a first interfacial sub-layer comprising silicon oxide on a surface of the substrate and forming a second interfacial sub-layer comprising a metal silicate on the first interfacial sub-layer. The second interfacial sub-layer may be formed by a cyclical deposition process, such as an atomic vapor deposition process.

In some embodiments, the interfacial layer comprises a bilayer of a first interfacial sub-layer comprising silicon oxide and a second interfacial sub-layer comprising a metal silicate disposed on the first interfacial sub-layer. The first interfacial sub-layer may be relatively thin (e.g., having a thickness between about 3 and about 10 Angstroms, or between about 4 and about 10 Angstroms). The metal silicate of the second interfacial sub-layer may include one or more of a transition metal or a rare earth metal. By way of particular examples, the metal silicate of the second interfacial layer may include one or more of Sc and Lu. In other words, the metal silicate of the second interfacial layer may be or include a scandium silicate or a lutetium silicate. The second interfacial sub-layer may be relatively thin (e.g., having a thickness between about 2 and about 7 Angstroms, or between about 3 and about 5 Angstroms).

In some embodiments, forming at least a portion of the interfacial layer includes providing a first layer comprising silicon oxide on a surface of the substrate, and doping the first layer with a dopant comprising a metal. In some embodiments, providing the first layer may include one or more of providing a substrate with a silicon oxide. In some embodiments, forming at least a portion of the interfacial layer includes forming a first layer comprising silicon oxide on a surface of the substrate, and doping the first layer with a dopant comprising a metal The dopant may be or include a transition metal or a rare earth metal. By way of particular examples, the dopant may be or include one or more of Sc, Lu, Tm, La, Y, and Al. Doping the first layer may include providing a dopant precursor to the reaction chamber, and performing a treatment, wherein the treatment includes one or more of a thermal anneal, a microwave anneal, or generating a plasma. The treatment may drive the dopant into the first layer.

In some embodiments, the interfacial layer may be or include a silicon oxide doped with a dopant comprising a metal. The interfacial layer may include a silicon oxide with a gradient of dopant, with the highest concentration of dopant at a top surface of the interfacial layer. The interfacial layer may be relatively thin (e.g., having a thickness between about 4 and about 10 Angstroms, or between about 5 and about 8 Angstroms). The interfacial layer may include between about 0.1 at % and about 20 at % dopant.

The exemplary method may produce an interfacial layer, such as an interfacial layer of a gate stack, with desirable properties, such as a high band gap between the interfacial layer and the underlying substrate, a relatively high dielectric constant, and a relatively low EOT or CET.

In accordance with further examples of the disclosure, a device is formed using a method and/or includes a structure as described herein.

In accordance with yet further exemplary embodiments of the disclosure, a system is provided for performing a method and/or for forming a structure as described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWINGS

FIG. 1 illustrates a method for forming a structure, such as a gate stack, in accordance with one or more embodiments of the disclosure;

FIG. 2 illustrates a method for forming an interfacial layer in accordance with one or more embodiments of the disclosure;

FIG. 3 illustrates a method for forming a second interfacial sub-layer in accordance with one or more embodiments of the disclosure;

FIG. 4 illustrates another method for forming an interfacial layer in accordance with one or more embodiments of the disclosure;

FIG. 5 illustrates a method for doping a first layer in accordance with one or more embodiments of the disclosure;

FIG. 6 illustrates an example of a substrate processing apparatus in accordance with one or more examples of the disclosure;

FIG. 7 illustrates an example of a structure that can form part of a device in accordance with one or more examples of the disclosure;

FIG. 8 illustrates another example of a structure that can form part of a device in accordance with one or more examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, devices, and systems provided below is merely exemplary and is intended for purposes of illustration only; the following description is not intended to necessarily limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As used herein, the term “and/or” includes any and all combinations of one or more of the associated listed items. Unless otherwise noted, expressions such as “at least one of,” when preceding a list of elements, modify the entire list of elements and do not necessarily modify the individual elements of the list.

As used herein, the singular forms “a,” “an,” and “the” are intended to include the singular and plural forms as well, unless the context indicates otherwise.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material. By way of example, a substrate can include silicon or silicon germanium. In some cases, the substrate can include an oxide (e.g., silicon oxide).

The terms “precursor” and “reactant” can refer to molecules or compounds that participate in a chemical reaction that produces a layer or deposited material. A precursor typically contains portions that are at least partly incorporated into a layer. Such resulting portions may be deposited on a substrate to form a film as disclosed herein. A reactant may be a compound that is incorporated into the layer or that is not incorporated into the resulting layer to a significant extent. In some cases, the term reactant can be used interchangeably with the term precursor.

As used herein, a “metal precursor” includes a gas or a material that can become gaseous and that can be represented by a chemical formula that includes one or more metals.

As used herein, “transition metal” refers to an element in groups 3-12 of the periodic table.

As used herein, “rare earth metal” refers to an element with an atomic number in the range of 57 to 71.

As used herein, a “silicon precursor” includes a gas or a material that can become gaseous and that can be represented by a chemical formula that includes silicon.

As used herein, a “oxidizing reactant” includes a gas or a material that can become gaseous and that can be represented by a chemical formula that includes oxygen.

In some embodiments, “film” refers to a layer extending in a direction perpendicular to a thickness direction. In some embodiments, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using one or more deposition cycles.

As used herein, the term “purge” can refer to a procedure in which an inert or substantially inert gas is provided to a reaction chamber in between two pulses of gases that might otherwise react with each other. For example, a purge, e.g., using an inert gas, such as a noble gas, may be provided between a precursor pulse and a reactant pulse to reduce gas phase interactions between the precursor and the reactant that might otherwise occur. It shall be understood that a purge can be affected either in time or in space, or both. For example, in the case of temporal purges, a purge step can be used, e.g., in the temporal sequence of providing a precursor to a reaction chamber, providing a purge gas to the reaction chamber, and providing a reactant or another precursor to the reaction chamber, wherein the substrate on which a layer is deposited does not move. In the case of spatial purges, a purge step can take the following form: moving a substrate from a first location to which a precursor is (e.g., continually) supplied, through a purge gas curtain, to a second location to which a reactant or other precursor is (e.g., continually) supplied.

As used herein, the term “structure” can refer to a partially or completely fabricated device structure. By way of examples, a structure can be a substrate or include a substrate with one or more layers and/or features formed thereon.

As used herein, the term “overlying” can refer to a film (e.g., directly) on top of another film.

As used herein, the term “cyclical deposition process” or “cyclic deposition process” can refer to a vapor deposition process in which deposition cycles, typically a plurality of consecutive deposition cycles, are conducted in a process chamber. Cyclic deposition processes can include, for example, cyclic chemical vapor deposition (CCVD) and/or atomic layer deposition (ALD) processes.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. For example, values of variables may include +/−20%, or +/−10%, or +/−5%, or +/−1%, or +/−0% of the value of the listed variable. Further, in this disclosure, the terms “comprising,” “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

A carrier and/or inert gas can be (e.g., continuously) co-flowed throughout any steps or sub-steps of any methods described herein. By way of example, a carrier and/or an inert gas can be one or more of helium, argon, or nitrogen.

Various steps of methods described herein can be performed within a single reaction chamber or can be performed in multiple reaction chambers, such as reaction chambers of a cluster tool. In some embodiments, the method may take place in a single reaction space. In some embodiments, one or more steps or substeps of methods described herein may take place in different reaction spaces and/or different reaction chambers.

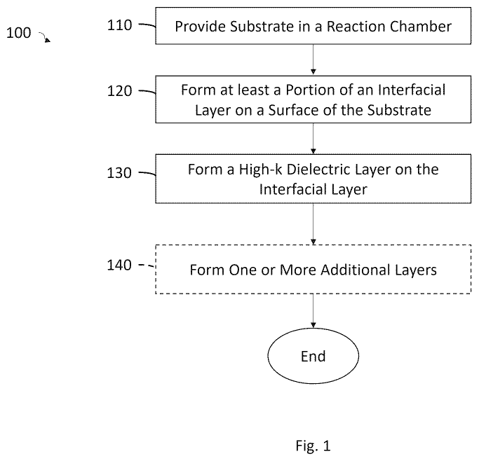

FIG. 1 illustrates a method 100 for forming a structure, such as a gate stack, in accordance with exemplary embodiments of the disclosure. Method 100 includes providing a substrate within a reaction chamber (step 110), forming at least a portion of an interfacial layer on a surface of the substrate (step 120), forming a high-k dielectric layer (e.g., directly) on the interfacial layer (step 130), and optionally forming one or more additional layers (step 140).

During step 110, a substrate is provided into a reaction space in a reaction chamber. In accordance with examples of the disclosure, the reaction chamber can form part of a chemical vapor deposition reactor, such as a chemical vapor deposition (CVD) reactor, an atomic layer deposition (ALD) reactor, or the like.

During step 110, the substrate can be brought to a desired temperature and/or the reaction space can be brought to a desired pressure, such as a temperature and/or pressure suitable for subsequent steps. By way of examples, a temperature (e.g., of a substrate, a substrate support, or an environment) within a reaction space can be between about 0° C. and about 500° C., or between about 250° C. and about 425° C. A pressure within a reaction space can be less than 760 torr, or between about 1 torr and 500 torr, or between about 1 torr and about 100 torr.

In some embodiments, the substrate comprises a surface comprising a semiconductor, such as silicon or silicon germanium. In some embodiments, the surface comprises a silicon channel. In some embodiments, the surface comprises silicon oxide. In some embodiments, providing the substrate in the reaction chamber (step 110) comprises providing a portion of the interfacial layer.

The method 100 continues with forming at least a portion of an interfacial layer (e.g., directly) on the surface of the substrate (step 120). The interfacial layer comprises silicon, oxygen, and one or more metals. In some embodiments, the interfacial layer comprises silicon, oxygen, and one or more transition and/or rare earth metals. In some embodiments, the interfacial layer comprises silicon, oxygen, and one or more of Sc and Lu.

The interfacial layer, as formed by methods herein, may have desirable properties. In some embodiments, the interfacial layer has a dielectric constant above 3.9, or above 5, or above 8, or above 10. In some embodiments, the interfacial layer has an EOT between about 5 Angstroms to about 15 Angstroms, or between about 7 Angstroms and 13 Angstroms.

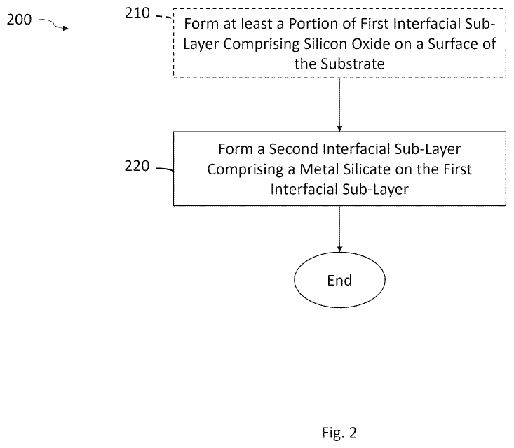

FIG. 2 illustrates a method 200 suitable for step 120 in FIG. 1. Method 200 comprises optionally forming at least a portion of a first interfacial sub-layer comprising silicon oxide (e.g., directly) on the surface of the substrate (step 210) and forming a second interfacial sub-layer comprising a metal silicate (e.g., directly) on the first sub-layer (step 220). Method 200 may produce an interfacial layer comprising a bilayer of the second interfacial sub-layer disposed directly on or overlying the first interfacial sub-layer.

A person with ordinary skill in the art will recognize that, in some embodiments, the first interfacial sub-layer is (e.g., completely) provided on the surface of the substrate in step 110 of method 100, or, in other embodiments, the first interfacial sub-layer is (e.g., completely) formed on the surface of the substrate in step 210 of method 200, or, in other embodiments, a portion of the first interfacial sub-layer is composed of a silicon oxide provided on the surface of the substrate in step 110 of method 100 and a portion of the first interfacial sub-layer is composed of a silicon oxide formed on the surface of the substrate in step 210 of method 200.

Forming at least a portion of the first interfacial sub-layer (step 210) comprises forming a silicon oxide on a surface of the substrate. The silicon oxide may be formed by any suitable method. In some embodiments, the silicon oxide is formed using an oxidation process of silicon on the surface of the substrate, a chemical vapor deposition process, and/or a cyclical deposition process. In some embodiments, the silicon oxide is formed using an oxidation process that comprises one or more of exposing the substrate to oxygen radicals or oxygen-containing gas, such as a gas comprising ozone, and/or exposing the substrate to a liquid comprising ozone dissolved in H₂O at a temperature in the range of about 0° C. to about 100° C.

In some embodiments, the first interfacial sublayer has a thickness between about 3 Angstroms and about 10 Angstroms, or between about 4 Angstroms and about 8 Angstroms. The first interfacial sub-layer is disposed (e.g., directly) on silicon in the surface of the substrate.

Forming the second interfacial sub-layer comprising a metal silicate (step 220) may be achieved by any suitable method. In some embodiments, forming the second interfacial sub-layer comprising a metal silicate (step 220) comprises performing a cyclical deposition process, such as an atomic layer deposition process.

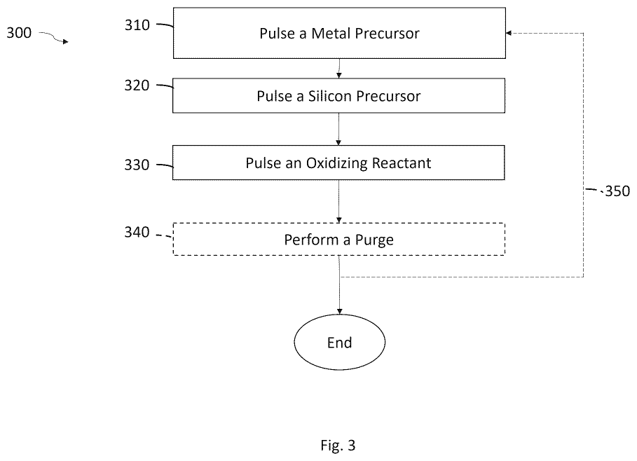

FIG. 3 illustrates a method 300 suitable for step 220 in FIG. 2. Method 300 comprises pulsing a metal precursor (step 310), pulsing a silicon precursor (step 320), pulsing an oxidizing reactant (step 330), optionally performing a purge (step 340), and optionally repeating the steps one or more times (loop 350). In some cases, the steps 310-340 of method 300 may be performed in any order. Each step 310-340 of method 300 may be performed once or a plurality of times before proceeding to the next step. In some embodiments, a purge, such as purge 340, is performed after any or all of the steps 310-330 of pulsing a metal precursor 310, pulsing a silicon precursor 320, and pulsing an oxidizing reactant 330. In some embodiments, no fluorides are provided to the reaction chamber during method 300.

In some embodiments, the metal precursor comprises one or more rare earth metal and/or one or more transition metals. In some embodiments, the metal precursor comprises one or more of Sc and Lu. In some embodiments, the metal precursor comprises a halide or a metalorganic. By way of examples, the metal precursor may be or comprise one or more of ScCl₃, Sc(amd)₃, Sc(acac)₃, LuCl₃, Lu(iPrAMD)₃, and Lu(iPrCp)₃.

The silicon precursor comprises silicon. Exemplary silicon precursors may be or include silanes, chlorosilanes, organosilanes, and silicon halides. By way of particular examples, the silicon precursor can be or include one or more of silane (SiH₄), disilane, SiCl₄, dichlorosilane, BTBAS, and TDMAS.

The oxidizing reactant comprises oxygen. By way of examples, the oxidizing reactant may be or comprise H₂O, O₂, O₃, H₂O₂, and oxygen radicals.

In some embodiments, two or three of: the metal precursor, the silicon precursor, and the oxidizing reactant comprise the same compound. For example, the metal precursor and the silicon precursor may comprise the same compound comprising a metal and silicon.

In some embodiments, the metal silicate formed during step 220 comprises one or more of a transition metal or a rare earth metal. In some embodiments, the metal silicate comprises one or more of Sc and Lu. By way of examples, the metal silicate comprises scandium silicate or lutetium silicate. In some embodiments, the second interfacial sub-layer has a thickness between about 2 Angstroms and about 7 Angstroms, or between about 3 Angstroms and about 5 Angstroms. The second interfacial sub-layer is disposed (e.g., directly) on the first interfacial sub-layer.

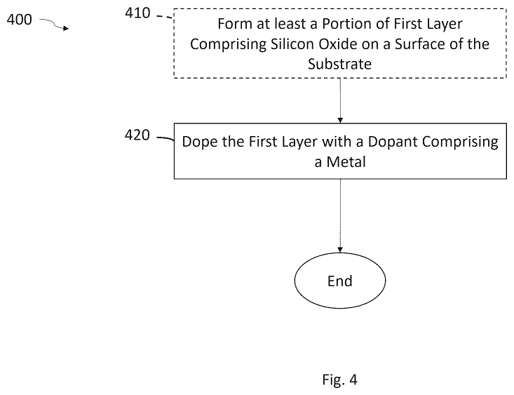

FIG. 4 illustrates another method 400 suitable for forming at least a portion of an interfacial layer (step 120 in FIG. 1). Method 400 comprises optionally forming at least a portion of a first layer comprising silicon oxide on the surface of the substrate (step 410) and doping the first layer with a dopant comprising a metal (step 420). In some embodiments, method 400 produces an interfacial layer comprising silicon oxide doped with a metal. In some embodiments, the interfacial layer comprises silicon oxide doped with one or more of rare earth metals and/or transition metals. In some embodiments, the interfacial layer comprises silicon oxide doped with one or more of Sc, Lu, Tm, La, Y, and Al. In some embodiments, the interfacial layer comprises between about 0.1 at % and about 20 at % dopant, or between about 2 at % and 10 at % dopant, or between about 5 at % and about 8 at % dopant.

A person with ordinary skill in the art will recognize that, in some embodiments, the first layer is (e.g., completely) provided on the surface of the substrate in step 110 of method 100, or, in other embodiments, the first layer is (e.g., completely) formed on the surface of the substrate in step 410 of method 400, or, in other embodiments, a portion of the first layer is composed of a silicon oxide provided on the surface of the substrate in step 110 of method 100 and a portion of the first layer is composed of a silicon oxide formed on the surface of the substrate in step 410 of method 400.

In some embodiments, forming at least a portion of the first layer (step 410) comprises forming a silicon oxide on a surface of the substrate. The silicon oxide may be formed by any suitable method. In some embodiments, forming the silicon oxide comprises an oxidation process of silicon on the surface of the substrate, a chemical vapor deposition process, or a cyclical deposition process. In some embodiments, the oxidation process comprises one or more of exposing the substrate to oxygen radicals or oxygen-containing gas, such as a gas comprising ozone, and/or exposing the substrate to a liquid comprising ozone dissolved in H₂O at a temperature in the range of about 0° C. to about 100° C.

In some embodiments, the first layer has a thickness between about 4 Angstroms and about 10 Angstroms, or between about 5 Angstroms and about 8 Angstroms. The first layer is disposed (e.g., directly) on silicon in the surface of the substrate.

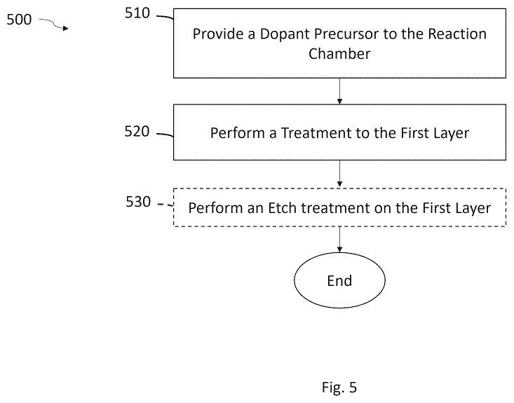

Doping the first layer (step 420) may be achieved by any suitable method. FIG. 5 illustrates a method 500 suitable for step 220 in FIG. 2. Method 500 comprises providing a dopant precursor to the reaction chamber (step 510), performing a treatment to the first layer (step 520), and optionally performing an etch treatment on the first layer (step 530).

In some embodiments, providing a dopant precursor comprises the dopant precursor or a component of the dopant precursor chemisorbing to the surface of the first layer. In some embodiments, performing a treatment to the first layer comprises driving the dopant into the first layer.

In some embodiments, the dopant precursor comprises one or more transition metals and/or rare earth metals. In some embodiments, the dopant precursor comprises one or more of Sc, Lu, Tm, La, Y, and Al. In some In some embodiments, the metal precursor comprises a halide (e.g., a chloride) or a metalorganic.

In some embodiments, performing the treatment 520 to the first layer comprises doping the first layer with nitrogen. In some embodiments, doping the first layer with nitrogen comprises generating a nitrogen plasma and/or exposing the substrate to the nitrogen plasma or species generated by the nitrogen plasma. In some embodiments, the nitrogen plasma is formed from a nitrogen-containing gas and optionally an inert gas. In some embodiments, the nitrogen-containing gas comprises one or more of nitrogen (N₂), ammonia (NH₃), and/or N2H2 (look up common).

The etch treatment may be any suitable treatment to remove material from the substrate. In some embodiments, performing the etch treatment comprises performing a wet etch treatment. In some embodiments, the wet etch treatment comprises exposing the substrate to one or more of hydrogen peroxide and phosphoric acid. In some embodiments, the etch treatment removes excess dopant precursor from a top surface of the first layer.

Turning back to FIG. 1, the method 100 continues with forming a high-k dielectric (e.g., directly) on the interfacial layer (step 130). The high-k dielectric layer may be formed by any suitable method. In some embodiments, forming the high-k dielectric layer comprises a chemical vapor deposition process or a cyclical deposition process. In some embodiments, the high-k dielectric layer has a dielectric constant above 3.9, or above 10, or above 15, or above 20. In some embodiments, the high k-dielectric comprises one or more of hafnium and zirconium. In some embodiments, the high-k dielectric comprises one or more of hafnium oxide, zirconium oxide, or hafnium zirconium oxide. In some embodiments, the high-k dielectric layer has a thickness less than 1.5 nm, or between about 1 nm and about 1.5 nm.

The method 100 continues with optionally forming one or more additional layers (step 140). The one or more additional layers may complete a gate stack. In some embodiments, the one or more additional layers comprise a conductive layer, such as TiN or TaN. The one or more additional layers may be formed by any suitable method. In some embodiments, forming the one or more additional layers comprises a chemical vapor deposition process or a cyclical deposition process.

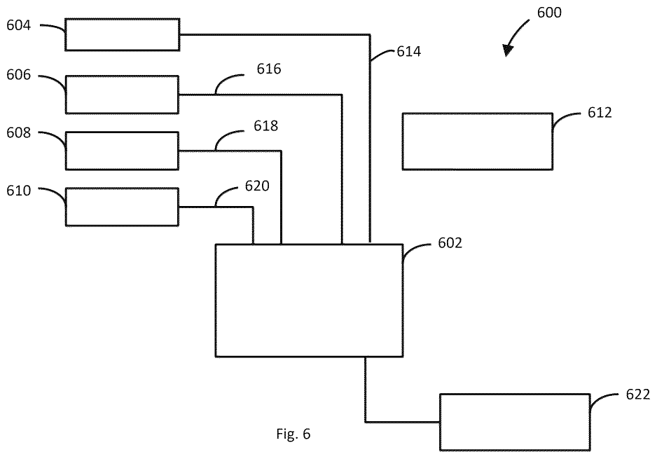

FIG. 6 illustrates an example of a substrate processing apparatus 600 in accordance with one or more examples of the disclosure. Apparatus 600 can be used to perform a method as described herein and/or form a structure or device portion as described herein.

In the illustrated example, apparatus 600 includes one or more reaction chambers 602, a metal precursor gas source 604, an oxygen-containing gas source 606, a silicon source 608, an etch gas source 610, an exhaust source 622, and a controller 612.

Reaction chamber 602 can include any suitable reaction chamber, such as an atomic layer deposition (ALD) or chemical vapor deposition (CVD) reaction chamber.

Metal precursor gas source 604 can include a vessel and one or more precursors comprising a metal (such as the metal precursors or dopant precursors as described herein) alone or mixed with one or more carrier (e.g., inert) gases. Oxygen-containing gas source 606 can include a vessel and one or more reactants, precursors, or gases comprising oxygen (such as the oxidizing reactant) as described herein-alone or mixed with one or more carrier (e.g., inert) gases. Silicon source 608 can include a vessel and one and/or more precursor comprising silicon, as described herein-alone or mixed with one or more carrier (e.g., inert) gases. Etch gas source 610 can include a vessel and one or more of etch gases as described herein-alone or mixed with one and/or more carrier gases. Although illustrated with four gas sources 604-610, apparatus 600 can include any suitable number of gas sources, including gas sources for an inert gas, such as helium, argon, and nitrogen. Gas sources 604-610 can be coupled to reaction chamber 602 via lines 614-620, which can each include flow controllers, valves, heaters, and the like.

Exhaust source 622 can include one or more vacuum pumps.

Controller 612 includes electronic circuitry and software to selectively operate valves, manifolds, heaters, pumps, and other components included in the apparatus 600. Such circuitry and components operate to introduce precursors, reactants, and gases from the respective sources 604-610. Controller 612 can control timing of gas pulse sequences, temperature of the substrate and/or reaction chamber, pressure within the reaction chamber, and various other operations to provide proper operation of the apparatus 600. Controller 612 can include control software to electrically or pneumatically control valves to control flow of precursors, reactants, and purge gases into and out of the reaction chamber 602. Controller 612 can include modules such as a software or hardware component, e.g., a FPGA or ASIC, which perform certain tasks. A module can advantageously be configured to reside on the addressable storage medium of the control system and be configured to execute one or more processes or methods, as described herein.

Other configurations of apparatus 600 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into reaction chamber 602. Further, as a schematic representation of a system, many components have been omitted for simplicity of illustration, and such components may include, for example, various valves, manifolds, purifiers, heaters, containers, vents, and/or bypasses.

During operation of apparatus 600, substrates, such as semiconductor wafers (not illustrated), are transferred from, e.g., a substrate handling system to reaction chamber 602. Once substrate(s) are transferred to reaction chamber 602, one or more gases from gas sources 604-610, such as precursors, reactants, carrier gases, and/or purge gases, are introduced into reaction chamber 602.

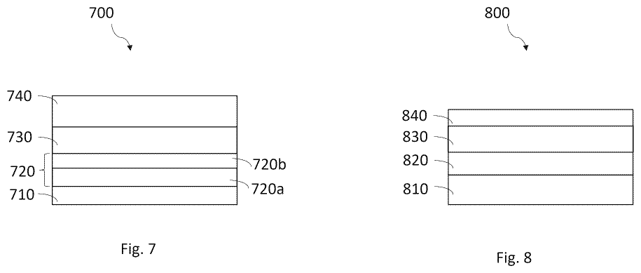

FIG. 7 illustrates a structure/a portion of a device 700 in accordance with additional examples of the disclosure. Device or structure 700 includes a substrate 710, an interfacial layer 720 comprising a first interfacial sub-layer 720a and a second interfacial sub-layer 720b, a high-k dielectric layer 730, and one or more additional layers 740. In some embodiments, the substrate 710 comprises a semiconductor, such as silicon or silicon germanium. In some embodiments, the interfacial layer 720 comprises silicon, oxygen, and one or more metals. In some embodiments, the interfacial layer 720 comprises silicon, oxygen, and one or more of Sc and Lu. In some embodiments, the interfacial layer 720 has a thickness less than 20 Angstroms or between about 5 Angstroms and about 15 Angstroms. In some embodiments, the first interfacial sub-layer 720a comprises silicon oxide. In some embodiments, the first interfacial sub-layer has a thickness between about 3 Angstroms and about 10 Angstroms, or between about 4 Angstroms and about 8 Angstroms. In some embodiments, the second interfacial sub-layer comprises a metal silicate. In some embodiments, the second interfacial sub-layer comprises one or more of scandium silicate and lutetium silicate. In some embodiments, the second interfacial sub-layer has a thickness between about 2 Angstroms and about 7 Angstroms, or between about 3 Angstroms and about 5 Angstroms. In some embodiments, the high-k dielectric layer 730 comprises a dielectric constant above 3.9, or above, 10, or above 20. In some embodiments, the high-k dielectric layer 730 comprises one or more of hafnium oxide, zirconium oxide, or hafnium zirconium oxide. In some embodiments, the high-k dielectric layer 730 has a thickness less than 1.5 nm, or between about 1 nm and about 1.5 nm. In some embodiments, the one or more additional layers 740 comprise a conductive layer, such as TiN or TaN.

FIG. 8 illustrates a structure/a portion of a device 800 in accordance with additional examples of the disclosure. Device or structure 800 includes a substrate 810, an interfacial layer 820, a high-k dielectric layer 830, and one or more additional layers 840. In some embodiments, the substrate 810 comprises a semiconductor, such as silicon or silicon germanium. In some embodiments, the interfacial layer 820 comprises silicon, oxygen, and one or more metals. In some embodiments, the interfacial layer 820 comprises silicon, oxygen, and one or more of Sc, Lu, Tm, La, Y, and Al. In some embodiments, the interfacial layer 820 comprises a doped silicon oxide. In some embodiments, the interfacial layer 820 comprises a silicon oxide doped with a dopant comprising one or more of Sc, Lu, Tm, La, Y, and Al. In some embodiments, the interfacial layer 820 comprises between about 0.1 at % and about 20 at % dopant, or between about 2 at % and 10 at % dopant, or between about 5 at % and about 8 at % dopant. In some embodiments, the interfacial layer 820 has a thickness between about 4 Angstroms and about 10 Angstroms, or between about 5 Angstroms and about 8 Angstroms. In some embodiments, the high-k dielectric layer 830 comprises a dielectric constant above 3.9, or above 10, or above 20. In some embodiments, the high-k dielectric layer 830 comprises one or more of hafnium oxide, zirconium oxide, or hafnium zirconium oxide. In some embodiments, the high-k dielectric layer 830 has a thickness less than 1.5 nm, or between about 1 nm and about 1.5 nm. In some embodiments, the one or more additional layers 840 comprise a conductive layer, such as TiN or TaN.

The example embodiments of the disclosure described above do not limit the scope of the invention, since these embodiments are merely examples of the embodiments of the invention, which are defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for forming a structure, the method comprising:
providing a substrate in a reaction chamber;
forming at least a portion of an interfacial layer on a surface of the substrate, wherein forming the portion of the interfacial layer comprises:
forming at least a portion of a first interfacial sub-layer comprising silicon oxide on the surface,
forming a second interfacial sub-layer comprising a metal silicate on the first interfacial sub-layer; and
forming a high-k dielectric layer on the interfacial layer.

2. The method of claim 1, wherein the metal silicate comprises one or more of a transition metal or a rare earth metal.

3. The method of claim 1, wherein the metal silicate comprises one or more of Sc and Lu.

4. The method of claim 1, wherein a thickness of the interfacial layer is less than 20 Angstroms.

5. The method of claim 1, wherein the first interfacial sub-layer has a thickness between about 3 Angstroms and 10 Angstroms.

6. The method of claim 1, wherein the second interfacial sub-layer has a thickness between about 2 Angstroms and 7 Angstroms.

7. The method of claim 1, wherein forming the second interfacial sub-layer comprises a cyclical deposition process.

8. The method of claim 1, wherein forming the portion of the first interfacial sub-layer comprises one or more of an oxidation process of the substrate, a chemical vapor deposition process, and a cyclical deposition process.

9. The method of claim 1, wherein the substrate comprises silicon, wherein forming at least a portion of the first interfacial sub-layer comprises an oxidation process of the silicon, wherein the oxidation process comprises one or more of exposing the substrate to oxygen radicals or oxygen-containing gas, such as a gas comprising ozone, and/or exposing the substrate to a liquid comprising ozone dissolved in H₂O at a temperature in the range of about 0° C. to about 100° C.

10. A method for forming a structure, the method comprising:
providing a substrate in a reaction chamber;
forming at least a portion of an interfacial layer on a surface of the substrate, wherein forming the portion of the interfacial layer comprises:
forming at least a portion of a first layer comprising silicon oxide on a surface of the substrate, and
doping the first layer with a dopant comprising a metal; and
forming a high-k dielectric layer on the interfacial layer.

11. The method of claim 10, wherein the dopant comprises a transition metal or a rare earth metal.

12. The method of claim 10, wherein the dopant comprises one or more of Sc, Lu, Tm, La, Y, and Al.

13. The method of claim 10, wherein the interfacial layer comprises between about 0.1 at % and about 20 at % dopant.

14. The method of claim 10, wherein the interfacial layer has a thickness between about 4 Angstroms and 10 Angstroms.

15. The method of claim 10, wherein doping the first layer comprises:
providing a dopant precursor to the reaction chamber, and
performing a treatment to the first layer, wherein the treatment comprises one or more of a thermal anneal, a microwave anneal, or generating a plasma.

16. The method of claim 15, wherein doping the first layer further comprises performing an etch treatment on the first layer.

17. The method of claim 10, further comprising exposing the substrate to a nitrogen plasma.

18. A structure, the structure comprising:
a substrate comprising a semiconductor;
an interfacial layer disposed on the semiconductor, wherein the interfacial layer comprises:
a first sub-layer comprising silicon oxide disposed on the semiconductor, and
a second sub-layer comprising a metal silicate disposed on the first sub-layer;
a high-k dielectric layer disposed on the second sub-layer; and
a conductive layer disposed on the high-k dielectric layer.

19. The structure of claim 18, wherein the first sub-layer has a thickness between about 3 Angstroms and about 10 Angstroms, and wherein the second sub-layer has a thickness between about 2 Angstroms and about 7 Angstroms.

20. The structure of claim 18, wherein the metal silicate comprises one or more of Sc and Lu.
